(19) United States
(12) Patent Application Publication
(10) Pub. No.: US 2018/0316179 A1
(43) Pub. Date: Nov. 1, 2018

(54) MULTI FUNCTION FAULT CIRCUIT INTERRUPTER DEVICE AND METHOD

(71) Applicant: EZ POWER LINES LTD, Netanya (IL)

(72) Inventor: Eran OFEK, Reut (IL)

(73) Assignee: EZ POWER LOINE LTD, Netanya (IL)

(21) Appl. No.: 15/769,067

(22) PCT Filed: Oct. 16, 2016
(86) PCT No.: PCT/IL2016/051123

§ 371 Date: Apr. 18, 2018

Related U.S. Application Data
(60) Provisional application No. 62/243,079, filed on Oct. 18, 2015.

(51) Int. Cl. H02H 3/16; G01R 31/02; H02H 5/12

(52) U.S. Cl. CPC H02H 3/165; H02H 5/12; G01R 31/025

(57) ABSTRACT

An interrupter device for controlling provision of grid power to its output terminals is adapted to sense, using low voltage, electrical parameters measurable between its output terminals and connect or avoiding connection of AC power to the output terminals based on the sensed parameters. The interrupter device is adapted to identify if any load is connected to the output terminals, whether that load is a living tissue, whether the load may pose too-high load or has ground-fault.

### BACKGROUND OF THE INVENTION

A circuit breaker is an automatically operated electrical switch designed to protect an electrical circuit from damage caused by overload or short circuit. Its basic function is to detect a fault condition and interrupt current flow. Unlike a fuse, which operates once and then must be replaced, a circuit breaker can be reset (either manually or automatically) to resume normal operation. Circuit breakers are made in varying sizes, from small devices that protect an individual household appliance up to large switchgear designed to protect high voltage circuits feeding an entire city. The circuit breaker contacts must carry the load current without excessive heating. Contacts are made of copper or copper alloys, silver alloys and other highly conductive materials.

A circuit breaker must detect a fault condition. An overload results when many devices consuming electricity from a single electrical circuit draw too much current. The circuit breaker performs one of its critical tasks: Trip before the overload damages the cable. In overload tripping, excessive current heats up a strip made up of two metals, called a bimetal. When the current exceeds the rating of the circuit breaker, the bimetal bends and eventually trips. Depending on intensity of the current, this may happen after seconds or even minutes. With short-circuit tripping, however, the circuit breaker must trip as quickly as possible. The bimetal is just too slow. That is why circuit breaker has a coil that reacts almost instantly to sudden current surges.

The service life of the contacts of a circuit breaker is limited by the erosion of contact material due to arcing while interrupting the current. In both cases, however, an electrical arc is produced between the contacts inside the circuit breaker and must be cleared immediately to avoid risk of fire. The arc is disperse by small metal plates dividing it into smaller arcs that dissipate quickly.

Ground Fault Circuit Interrupter (GFCI) is the electrical device designed to detect ground faults. Ground faults occur when electrical current is “leaking” somewhere outside of the path where the current is supposed to flow. If human body provides the path to ground for this leakage, one could be burned, or even electrocuted. GFCI constantly monitors electricity flowing in a circuit to sense any imbalance in the current to prevent shock hazards. If the current going into the circuit differs by even a small amount from that returning, the GFCI switches off the power to that circuit.

Commonly used technologies for GFCI are outdated and therefore reacting to ground fault event too slowly or too late, after too much energy was able to pass through to the ground. These are based upon loose induction coils that by their nature cannot provide fast readout of currents and not provide the high resolution required in order to improve their performances. Commonly used overload circuit breakers are based upon bimetal automatic switches, and therefore require high amount of energy to heat up and bend and by that open the circuit. They are expensive, slow reacting and cannot be configured for high resolution current sensing.

### SUMMARY OF THE INVENTION

An interrupter device for controlling provision of grid power to its output terminals is adapted to sense, using low voltage, electrical parameters measurable between its output terminals and connect or avoiding connection of AC power to the output terminals based on the sensed parameters. The interrupter device is adapted to identify if any load is connected to the output terminals, whether that load is a living tissue, whether the load may pose too-high load or has ground-fault.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a block diagram of a ground fault interrupter device according to some embodiments of the present invention;

FIG. 2 presents graphs of grid voltage U and of voltage E provided to an interrupter device of FIG. 1 according to embodiments of the invention. During the zero crossing periods of the AC as described in this figure, the system is monitoring the load's properties;

FIG. 3 presents the response of various types of loads connected at the output terminals of an interrupter device according to embodiments of the present invention; and

FIGS. 4A to 4D consecutive parts of a flow diagram presenting a method of operation of an interrupter device according to embodiments of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

A fault circuit interrupter device configured, for electrically interconnect an electrical load to an electric grid is disclosed. The interrupter has an input terminal connectable to the electric grid and an output terminal connectable to the load. The interrupter device may comprises:
(a) a switch, optionally a normally open switch, between the electric grid and the load;
(b) a circuit configured for detecting a ground fault event;
(c) a circuit configured to detect an event of existence of live tissue connected between the output port terminals;
(d) a circuit configured for monitoring the resistance character of the load, for example in order to detect a state of no current consumption event;
(e) a circuit configured to detect an over load event; and
(f) a controller adapted to control the switch so that the output terminal is not connected to the grid voltage supply when anyone of the events (a)-(f) is detected.

The fault circuit interrupter device may further comprise:
(a) a sampling unit configured for detecting the phase of the AC voltage at the grid input for measuring purposes and for supplying grid voltage to a power supply unit only when the input power voltage is between predefined phases of the AC sinusoid. The supplied power by the sampling unit may be provided to an energy storage component. The storage component may further be connected to an electronic circuit or circuits. The storage component may be charged to the voltage of the input AC sinusoid up to the voltage at which the storage component is disconnected from the input AC voltage, and may be discharged thereafter to the electronic circuits connected to it. The predefined phases at which the AC power is supplied to the energy storage component, and the storage capacity of which may be determined so that the voltage across the terminals of the storage unit fluctuates between the maximum voltage at the moment of disconnecting from the input AC voltage to a minimum voltage determined by the average consumed current by the connected electronic circuits and the capacity of the storage component. It would be apparent to those skilled in the art that these parameters may be calculated and selected so as to provide DC power with stable enough voltage. It would also be apparent that the storage component may be fed via any known rectifying circuitry so that the supplying of electrical energy to the storage component will be able to be done during the positive and negative halves of the AC sinusoid.
(b) a controller configured for measuring at least one electrical parameter from a list comprising voltage, current, resistance, capacitance, impedance and any combination thereof and/or said event of said load and energizing and de-energizing said load according said status thereof.

A device according to embodiments of the present invention is designed for prevention of the following adverse effects:
(a) ground fault event; (b) overload event; (c) electrification of a person without ground fault event; and (d) powering a line if no actual electrical load is connected. General principles of operation may be: the device may send “low voltage” portions of the AC sine wave, through an energy storage component or any other isolation mechanism, to the load ports by means of measuring components. If results of the analysis of the signal developing between the output ports of the device are within calculated or defined ranges, and there are no adverse effect events detected, a device built and operating according to embodiments of the present invention may provide the grid voltage to the load. Otherwise, the device keeps the provision of only low voltage pulses to the output ports for testing, until safe conditions are met, allowing to begin\renew power feed.

A device according to embodiments of the present invention may be configured to measure the resistance, capacitance and impedance at the output ports in order analyze several electrical features of the load, so as to prevent connection of grid power to the output ports of the device in case that a human tissue is detected to the ports of the device's output. A person touching the line/neutral ports may change the electrical features of the load, such as capacitance and resistance of the output ports as well as changes of the impedance signature as may be measured on the output ports of the device, for example in response to changes in the excitation testing voltage, such as frequency. In the case that a human tissue is detected between the output ports, the device will not connect the load to the power grid.

The proposed device may include (as a non-limiting example) a visible and/or audible indicator, such as an LCD, LED, buzzer, speaker etc., to indicate the status of the device, such as “the device's online powerl”, “offline status”, “problem detected”, “hazard detected”, etc. Such indication may be made by a prediction process or by an immediate detection of relevant parameters.

A device according to embodiments of the present invention may include automatic and/or manual controls, such as a switch, a microphone, various sensors etc, to allow manual and/or automatic override of the device's decision to connect or disconnect its output ports to/from the power grid.

A device according to embodiments of the present invention may include a mechanism to enable learning capabilities by analyzing the electrical profile of its output ports. Said analyzed electrical profile may be used as a reference value or for calibration of the device's logic in order to take better decisions regarding the detection of the objects connected to at least one of the output ports.

It is hence one object of the present application to disclose fault circuit interrupter device configured for electrically interconnect an electric grid and an electrical load. The interrupter may have an input terminal connectable to the electric AC grid and an output terminal connectable to the load. The fault circuit interrupter device may comprise:

(a) a switch, optionally a normally open switch, adapted to connect between the electric grid and the load;

(b) a circuit configured for detecting a ground fault event;

(c) a circuit configured to detect an event of existence of a live tissue between output terminal ports;

(d) a circuit configured for monitoring the electrical characters of the resistance of the load, to detect a state of no current consumption event;

(e) a circuit configured to detect an optional over load event ; and

(f) a controller adapted to control the switch so that the output terminal is not connected to the grid voltage supply when any of the above listed events is detected.

The circuit may further comprise:

(a) a sampling unit configured for detecting the phase of the AC voltage at the grid input for measuring purposes and for supplying grid voltage to a power supply unit only when the input power voltage is between predefined phases of the AC sinusoid, for supplying grid voltage at a phase of the AC sinusoid to an energy storage component, when AC voltage is in a dynamically defined range, and for discharging the energy stored in the energy storage component in a controlled way as required for self-powering;

(b) a controller configured for measuring at least one electrical parameter from a list comprising voltage, current, resistance, capacitance, impedance, temperature, arcing, leakages any combination thereof and/or for detecting occurrence of one or more events from the list of events herein above and for energizing or de-energizing the load according the status thereof.

Another object of the application is to disclose the character that is being examined of one or more of electric parameters selected from the group consisting of resistance, capacity, reactive impedance and any combination thereof.

Another object of the application is to disclose the method for automatically differentiating between a live tissue and any other object that is an optional electrical load, such as a home appliance etc.

A further object of the application is to disclose a list of fault-status conditions selectable from the group consisting of internal fault, overload condition, no-load condition, a value of at least one electrical parameter differing from a predetermined range.

A further object of the application is to disclose an indicator disposed in the interrupter device, configured for indicating at least one status of said device, selected from the group consisting of: online power, offline, an event detected, a fault detected, etc.

A further object of the application is to disclose the device provided with an energy storage component chargeable from the power grid when input voltage is at a desired voltage range and used for self-powering of the device and/or for testing of the output ports' status. The energy storage component is kept charged if there is no appliance connected to the output ports or if the connected appliance is not consuming any power from the output port.

A further object of the application is to disclose a method of electrically controlling the connection between an electric grid and a load via a fault interrupter device. The method may comprise the steps of:

(a) sensing electrical parameters of the input and output ports of the device. Such parameters may be selected from (i) resistance of the output ports; (ii) capacitance of the output ports; (iii) impedance of the output ports;

(b) controlling a switch to connect/disconnect the device input ports from its output ports. The switch may be controlled by a controller adapted to detect whether it is safe to interconnect input ports and output ports of the device, i.e. to allow provision of current to the load;

(c) providing a mechanism adapted to sense the current over the output ports in order to open the power switch in case that the current is zero for a defined period.

(d) providing a mechanism adapted to detect events of: over-load, ground fault, zero current consumption, and live tissue connected between ports, the mechanism is adapted to open the power switch when one of these events is detected.

It is still a purpose of the application to provide description of the step of monitoring of load status comprising:

(a) collecting grid energy in an energy storage component, at a preferred phase of the sinusoidal period of AC and periodically connecting that energy storage to output terminals of the device, when AC voltage is in a determined voltage range and connecting said energy storage component to the output terminal when this voltage is out-of-range of that determined voltage range;

(b) measuring at least one electric parameter of the electric parameters of the energy storage component, in order to determine whether storage component has been discharged through the output ports, which may mean that a load is connected to the output ports of the device;

(c) initiating load analysis to determine whether that load is eligible for powering from the electrical grid; and

(d) controlling a switch adapted to interconnect the power grid to the load according to the results of the load analysis.

A further object of the description of the invention is to disclose the step of providing grid voltage at a determined phase of the period of the sinusoid voltage of the AC input power to the output terminal, comprising rectifying obtained electric pulses. The proposed method may be performed in an automatic or a manual manner.

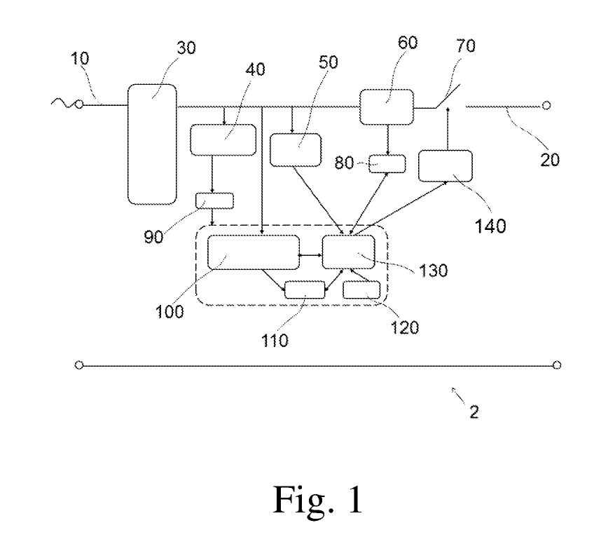

Reference is now made to FIG. 1, presenting a block diagram of a ground fault interrupter device 2 according to some embodiments of the present invention. Interrupter device 2 may comprise input terminal 10 connectable to an electric grid (not shown) and output terminal 20 connectable to a load (not shown). Device 2 may comprise overvoltage/overcurrent protection unit 30. Device 2 may further comprises full-wave rectifier 40, ground fault detector 60, power enable/disable switch 70 and driver thereof 140. Device 2 may further comprise low drop-out element 90, output voltage sampling unit 100, analogue-digital converters 80 and 110 and controller 130. Controller 130 may be adapted to perform the following functionalities
controlling sampling unit 100, which is adapted to supply grid voltage only at phases of the period of the input AC sinusoid to output terminals 20, through a sensing mechanism;
monitoring the load status (connected or disconnected);
monitoring resistance, capacitance and impedance of output ports 20 to determine whether the load present at output terminals 20 is a living tissue, such as that of a human, between Line and Neutral ports, or an eligible electrical load is connected to output terminals 20, thus allowing connecting of the eligible load to the power grid;
continuously and concurrently detecting over voltage/over current and ground fault;
energizing or de-energizing load according to occurrence of undue event(s) and the system's logic.

According to some embodiments of the present invention device 2 may be performed having some of its functionalities realized on a single chip and some other realized off the chip. For example, units 40, 60, 70 and 140 may be realized off-chip, while units 90, 100, 80, 110 and 130 may be realized on-chip. It would be apparent to those skilled in the art that other arrangements and manner of realization of the units of device 2 may be chosen.

In order to perform the above listed functionalities device 2 may operate as follows. When a load is connected to output ports 20 of device 2, output ports 20 will not be connected to the power grid until the load characteristics (such as: resistance profile, capacitance, impedance signature) are verified, to indicate that there is an eligible electrical load for connecting to the power grid.

After connection of a load is approved, device 2 may be adapted to interrupt interconnection between the electric grid at ports 10 and the load at ports 20 when overvoltage/overcurrent and/or ground fault are detected. In such situations power switch 70 may be operated to by gate driver 140, to open power switch 70.

The grid voltage may be provided to output terminal 20 only after it is recognized that an eligible electrical load is connected to the output terminal. A newly connected load that was just connected to device 2 is firstly provided with low voltage pulses (as specified for example below). After measuring of electric parameters of the load and confirming that the measured parameters are in the range as approved for connecting to the power grid, the power switch 70 may be closed by the gate driver 140, to apply grid voltage to output terminals 20 only after the load's parameters evident that the load is an eligible electrical load and that no living tissue is exemplified between output terminals 20. This way device 2 prevents casual electrocution of people exposed to electrocution by their nature, such as children. The proposed method may be performed either in automatic or in manual manner.

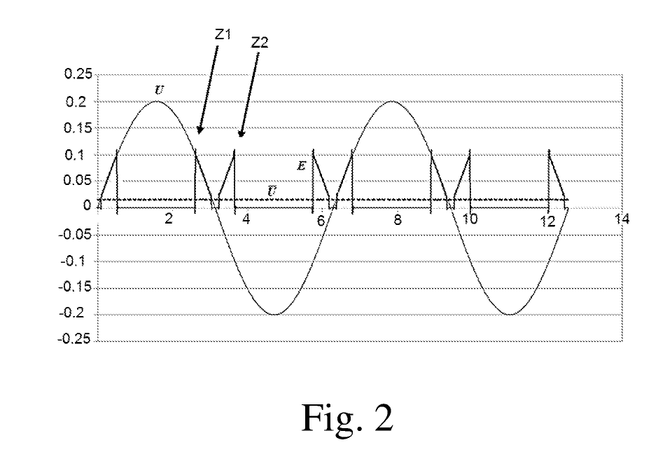

Reference is now made to Fig.2, presenting graphs of grid voltage U and of voltage E provided to device 2 of FIG. 1 according to embodiments of the invention, for sampling purposes and for providing low voltage source. In accordance with embodiments of the current invention, a sampling unit, such as sampling unit 100 (FIG. 1) of an interrupter device, such as device 2 (FIG. 1) may be configured for connecting the load device to an electrical power source when input voltage at the input terminals is in a predetermined range and disconnecting the load device from electrical power source when that voltage is out-of-range of that predetermined range. Thus, the electric voltage is supplied only at the specific instants when the voltage in the power source is within that predetermined range. As a result, at the output, the interrupter device provides a train of impulses E having predetermined amplitude, as dictated by the chosen predetermined range of the input sinusoidal voltage. These impulses can be used for charging an accumulating element or device such as a capacitor or an accumulator cell.

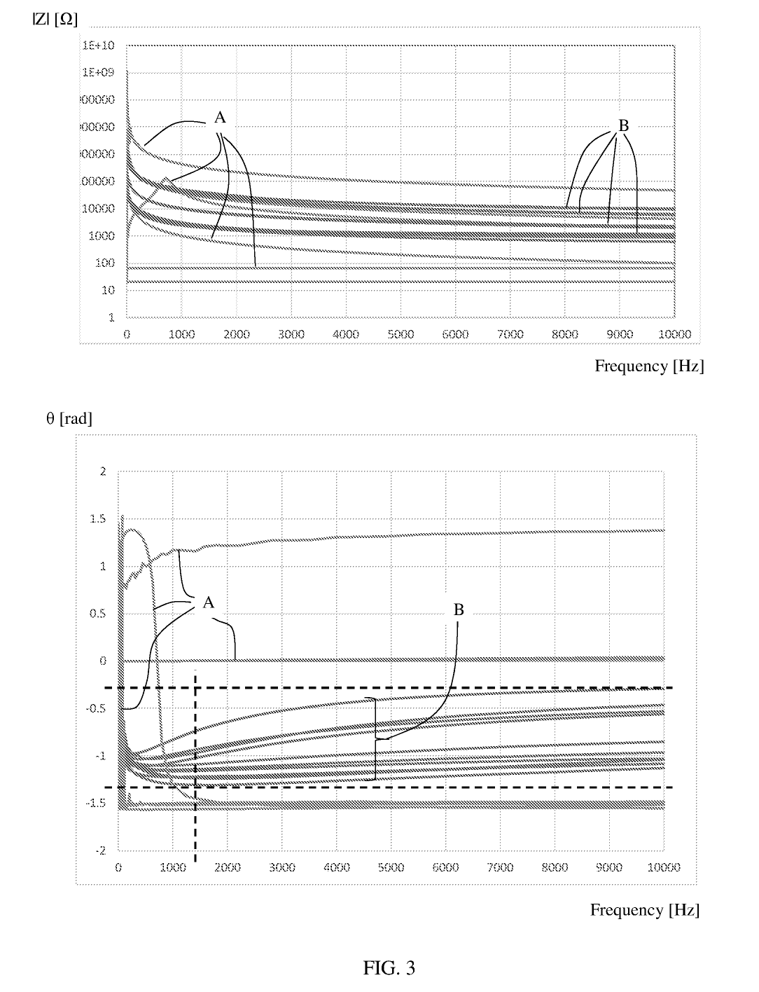

Reference is made now to FIG. 3, which presents the response of various types of loads connected at the output terminals of an interrupter device according to embodiments of the present invention (such as device 2 of FIG. 1), where in the upper graph the absolute value of the measured impedance is presented, substantially in the frequency range of 250 Hz to 10,000 Hz and in the lower graph the impedance phase Theta is presented in response to the change in the frequency of the excitation voltage, between 250 Hz and 10,000 Hz. The responses of the different types of loads are presented by the different graph lines as follows: lines A represent different types of eligible electrical loads, such as a toaster, a refrigerator, a microwave, a pot, a lamp, a spiral heater etc. Lines B represent frequency responses of various types of tissues representing living tissues, such as between two fingers of same hand, between fingers of two hands, between hand and leg, wet barefoot people or dry and isolated, through long metal bars or long extension cords or directly connected to the ports etc. As may be seen, while in the |Z| (electrical impedance) plane there is no characteristic difference between frequency responses of eligible electrical loads and that of tested tissues, in the impedance phase angle Theta there are substantial differences of eligible electrical loads and that of the tested tissues. For example, but not limited, in the range of 1500 Hz and higher the phase response Theta of the tested tissues reside in the range of −0.25 to −1.3 radians, while the phase response Theta of the various eligible electrical loads reside either from 0 to 1.5 radians or more or lower than −1.3 radians.. Thus, for example in the ranges described above, but not limited, the Theta responses of living tissues is substantially distinguished from that of eligible electrical loads. Accordingly, testing the phase angle response Theta of an object connected to the output terminals of an interrupter device, such as device 2 (FIG. 1) may provide highly distinguishable differences between eligible and non-eligible (i.e. living tissue) loads. Testing of the Theta response of a load connected to the output terminals may be done, according to embodiments of the present invention, using testing low-voltage pulses, thus ensuring the safety of the tested load, before its actual nature has been detected.

Detection of the value of the response phase Theta may be done as is known in the art, using adequate processes performed on a general purpose computing unit/controller such as unit 130 (FIG. 1) or using dedicated units, such as the AD5934 chip of Analog Devices of One Technology Way PO BOX 9106 Norwood, Mass. 02062, USA.

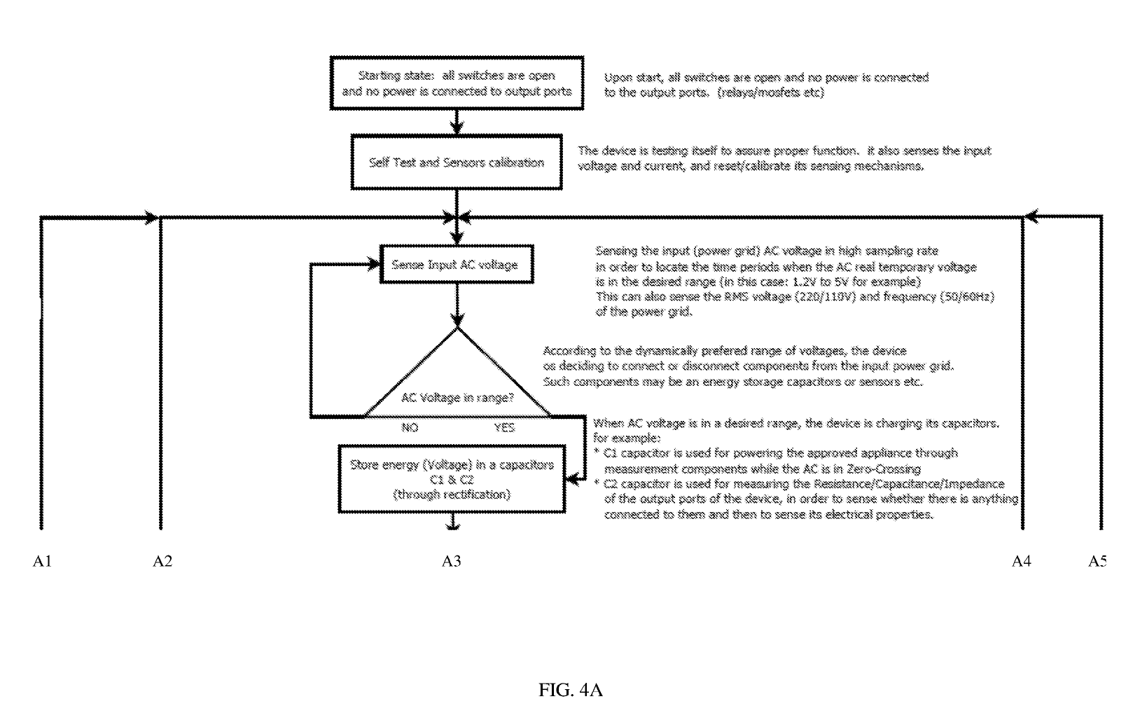

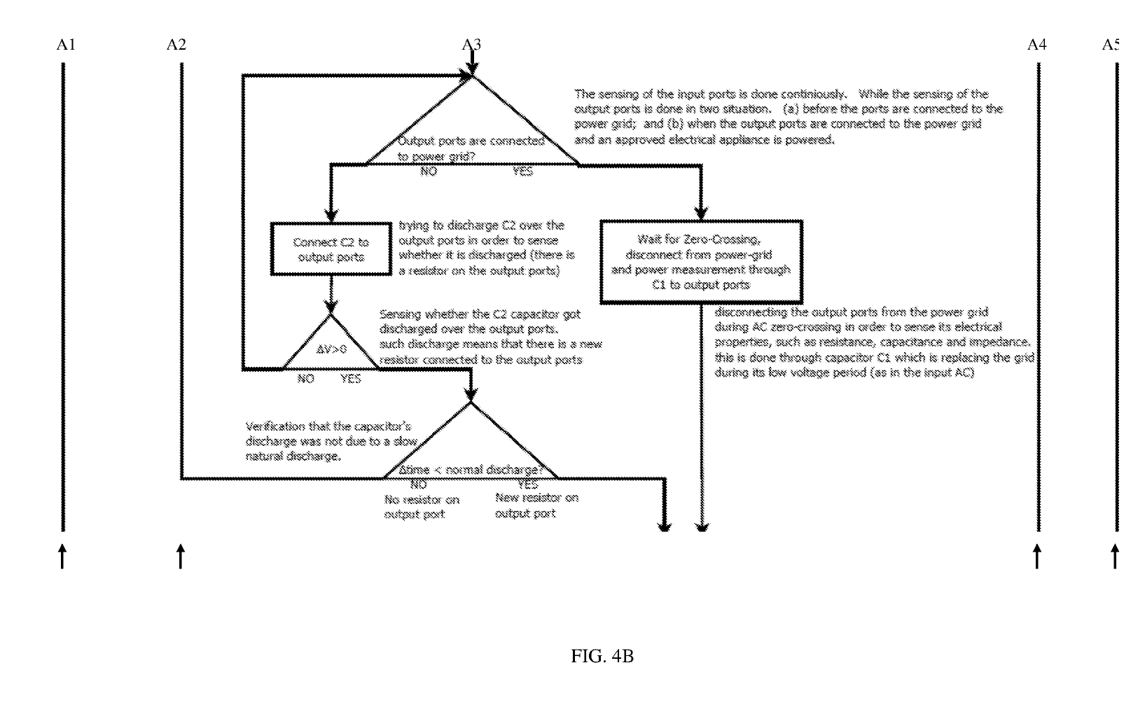

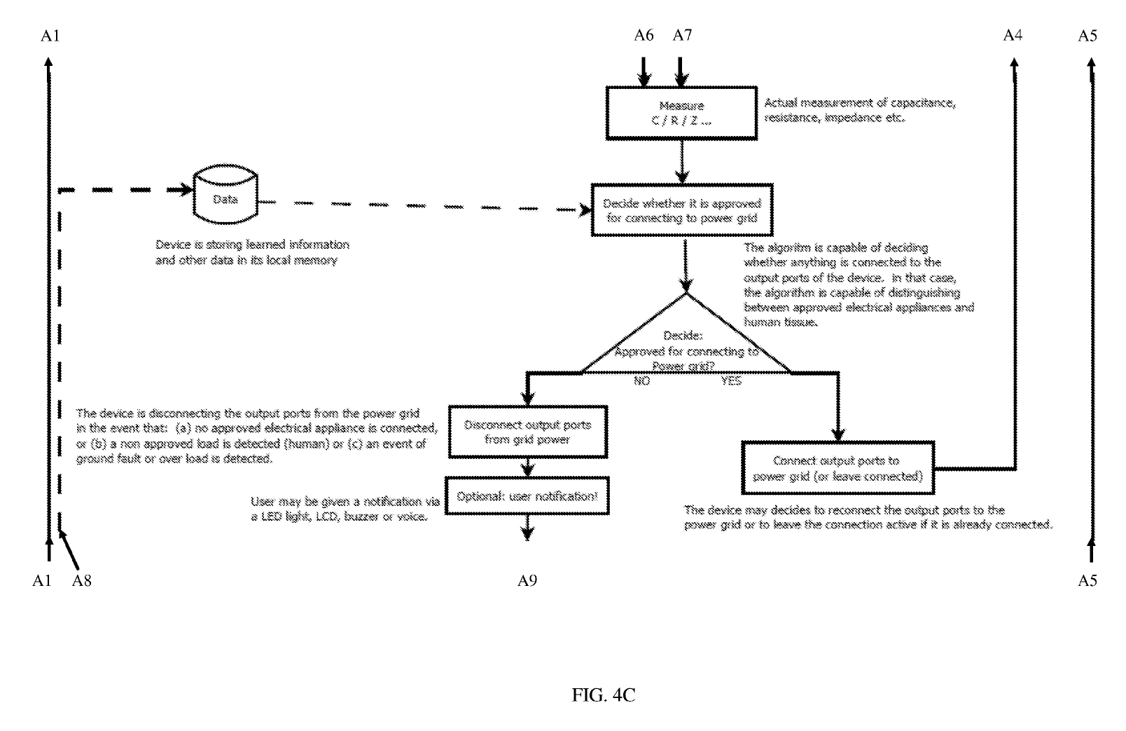

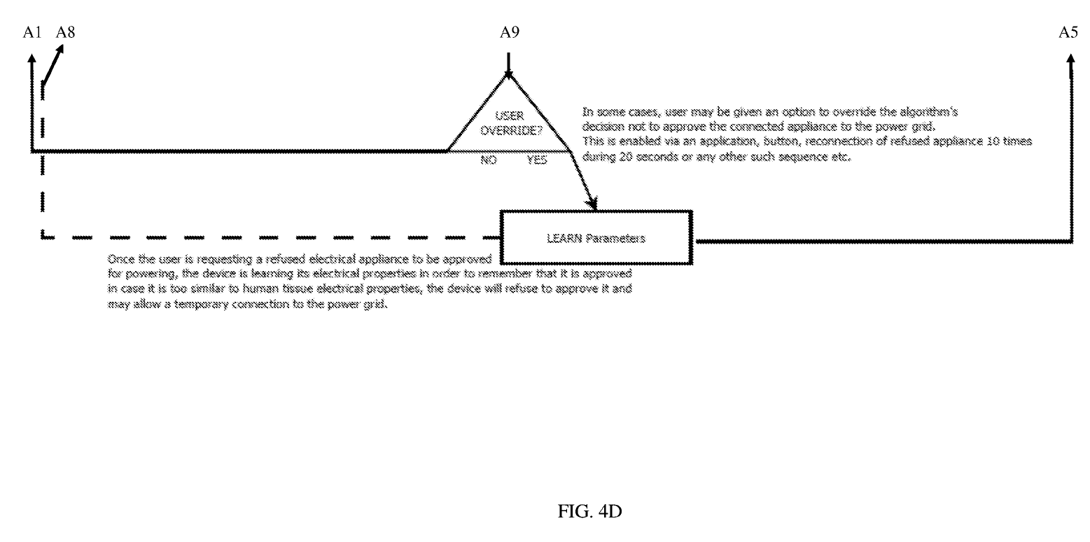

The process of testing the nature of a load connected to the output ports, testing whether any kind of load is connected the output ports and whether any condition/event preventing provision of AC power to the load connected to the output ports exist is described in a flow diagram in FIGS. 4A to 4D depict 4 consecutive parts of a flow diagram presenting a method of operation of an interrupter device according to embodiments of the present invention.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

1-14. (canceled)

15. A fault circuit interrupter device configured for electrically interconnecting an electric grid and a load, said interrupter having an input terminal connectable to said electric grid and an output terminal connectable to said load; said device comprising:
a. a switch; a sensing component, capable of sensing input and output terminals;
b. a circuit configured for detecting at least one electrical property of the load and generate an event when said property is outside dynamically configurable thresholds;
c. a circuit configured to sense at least one electrical property of a load connected to the output terminals for detecting whether there is a living tissue between the terminals;
d. a circuit configured for monitoring a status of said load and preventing grid voltage supply to said output terminal when said load status is undue; and
e. a controller adapted to control said switch so that said output terminal is prevented from grid voltage supply thereon when an event of ground fault and/or over load and/or human tissue is detected;
wherein said device comprises:
a. a sampling unit configured for supplying grid voltage at a phase of period of AC sinusoid to said output terminal, when AC voltage is in a determined range and rerouting said output terminal to an alternative power profiling circuitry when said AC sinusoid voltage is out-of-range, and
b. a controller configured with logic for measuring at least two electric properties of said load and energizing or de-energizing said load according said logic thereof.

16. The device according to claim 15, wherein said at least one electric parameter is selected from the group consisting of potential, current, resistance, capacitance, impedance and any combination thereof.

17. The device according to claim 15, wherein said undue status is selected from the list consisting of: internal fault, overheating fault, no-load condition, overload condition, current leakage detected, arcing detected, a live tissue is detected condition, a value of said electric parameter is outside a threshold range, a user command, a timer event, a scheduler event, a sensor event or in accordance to the system's logic.

18. The device according to claim 15, wherein said sampling unit is provided with a rectifying means.

19. The device according to claim 15 provided with an indicator configured for indicating at least one status selected from the list consisting of: online power, offline, fault detected, internal fault, overheating fault, no-load condition, overload condition, current leakage detected, arcing detected, a live tissue is detected condition, a value of said electric parameter is outside a threshold range, a user command, a timer event, a scheduler event, a sensor event or in accordance to the system's logic.

20. The device according to claim 15 adapted for automatic and manual operation.

21. The device according to claim 15 provided with a capacitor which is kept charged at low voltage and then connected to the ports of the load when there is no load detected at the ports; a pattern of drop in an electric potential on said capacitor over time indicates the connection of a load to the devices terminals; a load having resistance in an approved range is legitimate load for powering; said capacitor connectable to the load terminals during the AC zero crossing; between point Z1 and point Z2, the load is disconnected from the power grid and/or while the system is in standby mode waiting for a load to connect.

22. A method of electrically interconnecting an electric grid and a load; said method comprising the steps of:
a. providing a fault circuit interrupter device configured for electrically interconnecting an electric grid and a load, said interrupter having an input terminal connectable to said electric grid and an output terminal connectable to said load; said device comprising:
i. a switch normally open;
ii. a sensing component, capable of sensing input and output terminals;
iii. a circuit configured for monitoring a status of said load and preventing grid voltage supply to said output terminal when said load status is undue;
iv. a controller adapted to open said switch so that said output terminal is prevented from grid voltage supply thereon when a fault is detected and said undue load status are detected;
b. interconnecting said electric grid and a load by means of said device;
c. detecting a ground fault and/or any other fault;
d. monitoring a status and/or electric properties of said load; said switch is to disconnect said output terminal from grid voltage supply upon detection of at least one of the events from the list consisting of: internal fault, overheating fault, no-load condition, overload condition, current leakage detected, arcing detected, a live tissue is detected condition, a value of said electric parameter is outside a threshold range, a user command, a timer event, a scheduler event, a sensor event or in accordance to the system's logic;
wherein said step of monitoring of load status comprises:
a. supplying grid voltage at a phase of period of AC sinusoid to said output terminal, when AC voltage is in a determined range and rerouting said output terminal to an alternative power profiling circuitry when said AC sinusoid voltage is out-of-range, and
b. measuring at least two electric properties of said load and energizing or de-energizing said load according said logic thereof.

23. The method according to claim 22, wherein said electric parameter is selected from the list consisting of: electric impedance, ground leakage, current, voltage, arcing pattern, resistance, capacitance and any combination thereof.

24. The method according to claim 22, wherein said undue status is selected from the list consisting of: internal fault, overheating fault, no-load condition, overload condition, current leakage detected, arcing detected, a live tissue is detected condition, a value of said electric parameter is outside a threshold range, a user command, a timer event, a scheduler event, a sensor event or in accordance to the system's logic.

25. The method according to claim 22, wherein said step of providing grid voltage at a phase of period of AC sinusoid to said output terminal comprises rectifying obtained electric pulses.

26. The method according to claim 22 comprising a step of indicating at least one status of said device selected from the list consisting of: online power, offline, fault detected, internal fault, overheating fault, no-load condition, overload condition, current leakage detected, arcing detected, a live tissue is detected condition, a value of said electric parameter is outside a threshold range, a user command, a timer event, a scheduler event, a sensor event or in accordance to the system's logic.

27. The method according to claim 22 performed in automatic and manual manners.

28. The method according to claim 22 provided with a capacitor which is kept charged at low voltage and then connected to the ports of the load when there is no load detected at these ports; a pattern of drop in an electric potential on said capacitor over time indicates the connection of a load to the devices terminals; a load having resistance in an approved range is legitimate load for powering; said capacitor connectable to the load terminals during the AC zero crossing; between point Z1 and point Z2, the load is disconnected from the power grid and/or while the system is in standby mode waiting for a load to connect.
